(19) United States
(12) Patent Application Publication
(10) Pub. No.: US 2024/0316651 A1
(43) Pub. Date: Sep. 26, 2024

(54) COATED TOOL AND CUTTING TOOL

(71) Applicant: KYOCERA CORPORATION, Kyoto-shi, Kyoto (JP)

(72) Inventor: Kei YOSHIMI, Satsumasendai-shi, Kagoshima (JP)

(21) Appl. No.: 18/574,077

(22) PCT Filed: Jul. 5, 2022
(86) PCT No.: PCT/JP2022/026737

§ 371 Date: Dec. 26, 2023

(30) Foreign Application Priority Data
Jul. 30, 2021 (JP) 2021-125932

(51) Int. Cl. B23B 27/14; C23C 28/00

(52) U.S. Cl. CPC B23B 27/148; C23C 28/42; B23B 2222/04; B23B 2222/88; B23B 2224/08; B23B 2224/36; B23B 2228/08; B23B 2228/10; B23B 2228/36

(57) ABSTRACT

A coated tool disclosure includes a base body and a coating layer. The coating layer includes crystals having a cubic structure. The coating layer has a striped structure in cross-sectional observation by a transmission electron microscope. The striped structure has two layers alternately located in a thickness direction. The two layers contain Si and at least one metal element. The two layers each contain crystals having the cubic structure. When a lattice constant of a crystal having the cubic structure in one layer of the two layers is referred to as a first lattice constant and a lattice constant of a crystal having a cubic structure in the other layer of the two layers is referred to as a second lattice constant, a difference between a magnitude of the first lattice constant and a magnitude of the second lattice constant is greater than 0% and 0.1% or less.

### TECHNICAL FIELD

The present disclosure relates to a coated tool and a cutting tool.

### BACKGROUND OF INVENTION

As a tool used for cutting processing such as turning processing or milling processing, a coated tool is known in which a surface of a base body made of cemented carbide, cermet, ceramic, or the like is coated with a coating layer to improve wear resistance, and the like.

### CITATION LIST

### Patent Literature

Patent Document 1: JP 2020-146777 A

### SUMMARY

A coated tool according to an aspect of the present disclosure includes a base body and a coating layer located on the base body. The coating layer includes crystals having a cubic structure. The coating layer has a striped structure in cross-sectional observation by a transmission electron microscope. The striped structure has two layers alternately located in a thickness direction. The two layers contain Si and at least one metal element. The two layers are different from each other in terms of a content of the metal element. The two layers each contain crystals having the cubic structure. When a lattice constant of a crystal having the cubic structure in one layer of the two layers is referred to as a first lattice constant and a lattice constant of a crystal having the cubic structure in the other layer of the two layers is referred to as a second lattice constant, a difference between a magnitude of the first lattice constant and a magnitude of the second lattice constant is greater than 0% and 0.1% or less.

### BRIEF DESCRIPTION OF THE DRAWINGS

FIG. 1 is a perspective view illustrating an example of a coated tool according to an embodiment.

FIG. 2 is a side sectional view illustrating the example of the coated tool according to the embodiment.

FIG. 3 is a sectional view illustrating an example of a coating layer according to the embodiment.

FIG. 4 is a schematic enlarged view of a portion H illustrated in FIG. 3.

FIG. 5 is a schematic view for illustrating an Al content, a Cr content, and a Si content of a first layer and a second layer.

FIG. 6 is a front view illustrating an example of a cutting tool according to the embodiment.

FIG. 7 is a table showing a configuration of a coating layer and a measurement result of a lattice constant in Samples No. 1 to No. 6.

### DESCRIPTION OF EMBODIMENTS

The following is a detailed description of a coated tool and a cutting tool according to the present disclosure (hereinafter referred to as “embodiments”) with reference to the drawings. It should be noted that the coated tool and the cutting tool according to the present disclosure are not limited by the embodiments. Embodiments can be appropriately combined so as not to contradict each other in terms of processing content. In the following embodiments, the same portions are denoted by the same reference signs, and overlapping explanations are omitted.

In the embodiments described below, expressions such as “constant”, “orthogonal”, “perpendicular”, and “parallel” may be used, but these expressions do not need to be exactly “constant”, “orthogonal”, “perpendicular”, and “parallel”. In other words, each of the above-described expressions allows for deviations in, for example, manufacturing accuracy, positioning accuracy, and the like.

In the related art described above, there is room for further improvement in terms of enhancing thermal stability.

### Coated Tool

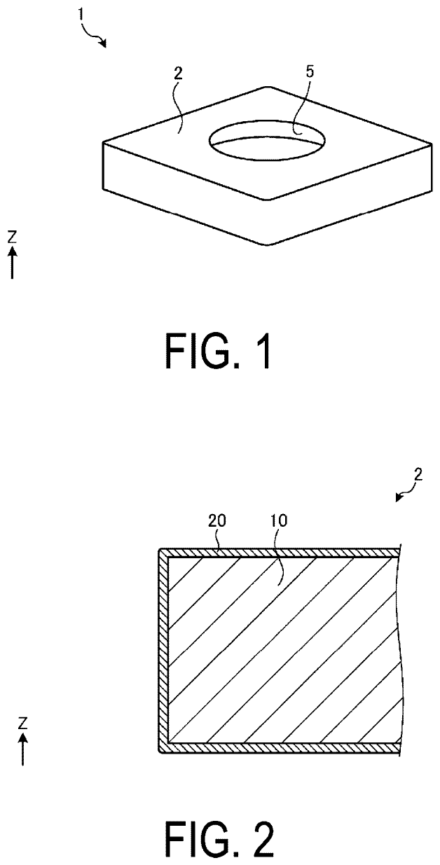

FIG. 1 is a perspective view illustrating an example of a coated tool according to an embodiment. FIG. 2 is a side sectional view illustrating an example of the coated tool 1 according to the embodiment. As illustrated in FIG. 1, a coated tool 1 according to the embodiment includes a tip body 2.

### Tip Body 2

The tip body 2 has a hexagonal shape in which a shape of an upper surface and a lower surface (a surface intersecting the Z-axis illustrated in FIG. 1) is a parallelogram.

One corner portion of the tip body 2 functions as a cutting edge portion. The cutting edge portion has a first surface (for example, an upper surface) and a second surface (for example, a side surface) connected to the first surface. In the embodiment, the first surface functions as a “rake face” for scooping chips generated by cutting, and the second surface functions as a “flank face”. A cutting edge is located on at least a part of a ridge line where the first surface and the second surface intersect with each other, and the coated tool 1 cuts a work material through application of the cutting edge to the work material.

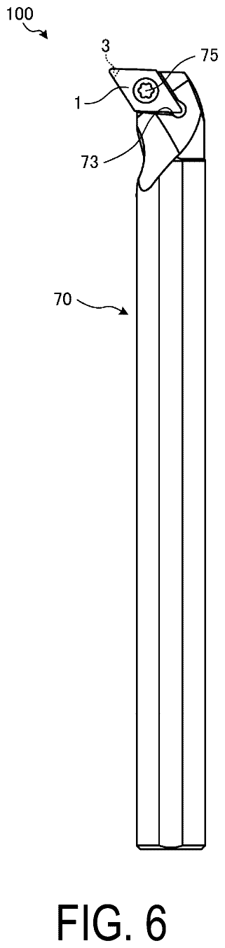

A through hole 5 that vertically penetrates the tip body 2 is located in the center portion of the tip body 2. A screw 75 for attaching the coated tool 1 to a holder 70 described below is inserted into the through hole 5 (see FIG. 6).

As illustrated in FIG. 2, the tip body 2 has a base body 10, and a coating layer 20.

### Base Body 10

The base body 10 is formed of, for example, cemented carbide. The cemented carbide contains tungsten (W), specifically, tungsten carbide (WC). Further, the cemented carbide may contain nickel (Ni) or cobalt (Co). Specifically, the base body 10 is made of WC-based cemented carbide containing WC particles as a hard phase component and Co as a main component of a binding phase.

Alternatively, the base body 10 may be formed of a cermet. The cermet contains, for example, titanium (Ti), specifically, titanium carbide (TiC) or titanium nitride (TiN). Furthermore, the cermet may contain Ni or Co.

The base body 10 may be formed of a cubic boron nitride sintered body containing cubic boron nitride (cBN) particles. The base body 10 is not limited to the cubic boron nitride (cBN) particles, and may contain particles such as hexagonal boron nitride (hBN), rhombohedral boron nitride (rBN) and wurtzite boron nitride (wBN).

### Coating Layer 20

The coating layer 20 is coated on the base body 10 for the purpose of, for example, improving wear resistance, heat resistance, and the like of the base body 10. In the example in FIG. 2, the coating layer 20 entirely coats the base body 10. The coating layer 20 may be located at least on the base body 10. When the coating layer 20 is located on a first surface (here, an upper surface) of the base body 10, the first surface has high wear resistance and heat resistance. When the coating layer 20 is located on a second surface (here, a side surface) of the base body 10, the second surface has high wear resistance and heat resistance.

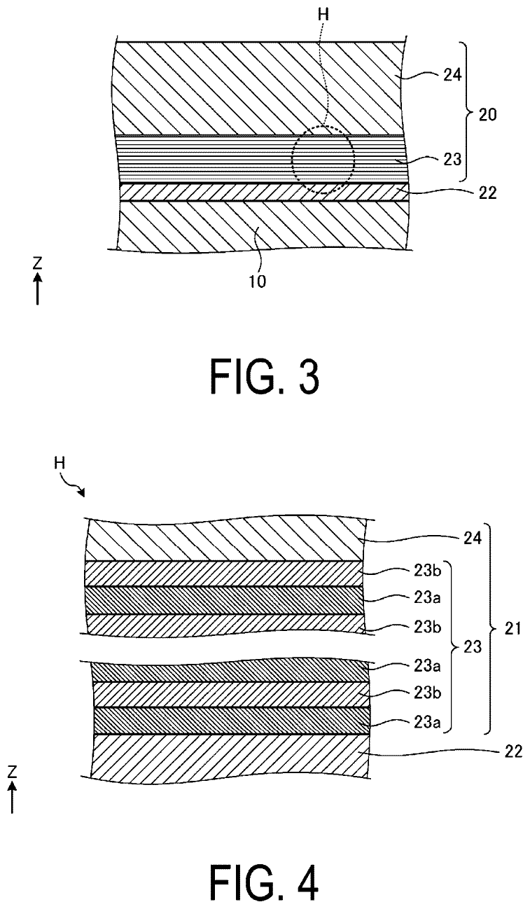

Here, a specific configuration of the coating layer 20 will be described with reference to FIGS. 3 and 4. FIG. 3 is a sectional view illustrating an example of the coating layer 20 according to the embodiment. FIG. 4 is a schematic enlarged view of a portion H illustrated in FIG. 3.

As illustrated in FIG. 3, the coating layer 20 includes a first coating layer 23 located on the intermediate layer 22, and a second coating layer 24 located on the first coating layer 23.

### First Coating Layer 23

The first coating layer 23 includes at least one element selected from the group consisting of Al, Group 5 elements, Group 6 elements, and Group 4 elements except for Ti, at least one element selected from the group consisting of C and N, Si, and Cr.

Specifically, the first coating layer 23 contains Al, Cr, Si, and N. That is, the first coating layer 23 may be an AlCrSiN layer containing AlCrSiN, which is a nitride of Al, Cr and Si. Note that the expression “AlCrSiN” means that Al, Cr, Si, and N are present at an arbitrary ratio, and does not necessarily mean that Al, Cr, Si, and N are present at a ratio of 1:1:1:1.

When the first coating layer 23 containing the metal (for example, Si) included in the intermediate layer 22 is located on the intermediate layer 22, the adhesion between the intermediate layer 22 and the coating layer 20 is high. This makes it difficult for the coating layer 20 to peel off from the intermediate layer 22, so the durability of the coating layer 20 is high.

As illustrated in FIG. 4, the first coating layer 23 may have a striped structure in cross-sectional observation by a transmission electron microscope. Specifically, the first coating layer 23 includes a plurality of first layers 23a and a plurality of second layers 23b. The first coating layer 23 has the first layers 23a and the second layers 23b alternately stacked in a thickness direction. The first layer 23a is a layer in contact with the intermediate layer 22, and the second layer 23b is formed on the first layer 23a.

The thickness of each of the first layer 23a and the second layer 23b may be 50 nm or less. Since the first layer 23a and the second layer 23b formed to be thin have small residual stresses and are less likely to cause peeling, cracking, or the like, the durability of the coating layer 20 is enhanced.

The first coating layer 23 may include crystals having a cubic structure. In this case, each of the first layer 23a and the second layer 23b may include crystals having a cubic structure.

The first layer 23a and the second layer 23b may contain Si and at least one metal element, and the content of the metal element may be different between the first layer 23a and the second layer 23b. The first layer 23a and the second layer 23b may have the same crystal orientation or may have different crystal orientations.

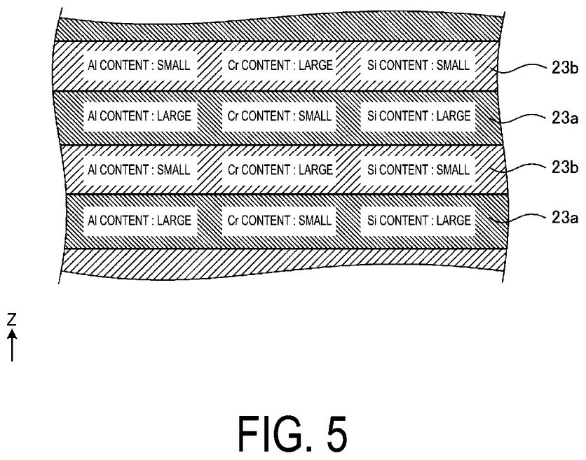

FIG. 5 is a schematic view for illustrating an Al content, a Cr content, and a Si content of the first layer 23a and the second layer 23b.

The first layer 23a and the second layer 23b may each contain Al, Cr, Si, and N. Here, the content of Al in the first layer 23a is referred to as the first Al content, the content of Cr in the first layer 23a is referred to as the first Cr content, and the content of Si in the first layer 23a is referred to as the first Si content. The content of Al in the second layer 23b is referred to as the second Al content, the content of Cr in the second layer 23b is referred to as the second Cr content, and the content of Si in the second layer 23b is referred to as the second Si content.

In this case, the first Al content may be greater than the second Al content, the first Cr content may be less than the second Cr content, and the first Si content may be greater than the second Si content.

The coated tool 1 including the first coating layer 23 having such a configuration has high hardness and excellent fracture resistance.

A sum of Al, Cr, and Si of the metal elements contained in the first coating layer 23 may be 98 atomic % or more.

The coated tool 1 including the first coating layer 23 having such a configuration has higher hardness and superior fracture resistance.

The ratio of Al in the metal elements of the first coating layer 23 may be 38 atomic % or more and 55 atomic % or less. The ratio of Cr in the metal elements of the first coating layer 23 may be 33 atomic % or more and 48 atomic % or less. The ratio of Si in the metal elements of the first coating layer 23 may be 4 atomic % or more and 15 atomic % or less.

The coated tool 1 including the first coating layer 23 having such a configuration has improved oxidation resistance and excellent wear resistance.

A difference between the first Al content and the second Al content may be 1 atomic % or more and 9 atomic % or less.

The coated tool 1 including the first coating layer 23 having such a configuration relaxes stress inside the coating layer and is excellent in wear resistance while maintaining high oxidation resistance and high hardness.

The coated tool 1 including the first coating layer 23 having such a configuration has particularly high hardness.

A difference between the first Cr content and the second Cr content may be 1 atomic % or more and 12 atomic % or less.

The coated tool 1 including the first coating layer 23 having such a configuration has superior wear resistance.

The coated tool 1 including the first coating layer 23 having such a configuration has particularly excellent fracture resistance.

A difference between the first Si content and the second Si content may be 0.5 atomic % or more and 5 atomic % or less.

The coated tool 1 including the first coating layer 23 having such a configuration has particularly high hardness.

The thickness of each of the first layer 23a and the second layer 23b may be 1 nm or greater and 20 nm or less.

The coated tool 1 including the first coating layer 23 having such a configuration has excellent hardness and fracture resistance.

The first coating layer may be formed by, for example, a physical vapor deposition method. Examples of the physical vapor deposition method may include an ion plating method and a sputtering method. For example, when fabricating the first coating layer by an ion plating method, the coating layer may be fabricated by the following method.

First, as an example, each metal target of Cr, Si, and Al, a composite alloy target, or a sintered body target is prepared.

Next, the target serving as a metal source is vaporized and ionized by arc discharge, glow discharge, or the like. The ionized metal is reacted with a nitrogen (N₂) gas of a nitrogen source and deposited on the surface of the base body. The AlCrSiN layer can be formed by the procedure described above.

In the above procedure, the temperature of the base body may be set to 500 to 600° C., the pressure may be set to 1.0 to 6.0 Pa, a direct-current bias voltage of −50 to −200 V may be applied to the base body, and the arc discharge current may be set to 100 to 200 A.

A composition of the first coating layer can be adjusted by independently controlling the voltage and current values at the time of arc discharge and glow discharge applied to the aluminum metal target, the chromium metal target, the aluminum-silicon composite alloy target, and the chromium-silicon composite alloy target, for each target. The composition of the first coating layer can be adjusted by controlling the coating time and the atmospheric gas pressure. In an example of the embodiment, an amount of ionization of the target metal can be changed by changing the voltage and current values at the time of arc discharge and glow discharge. By periodically changing the current value at the time of arc discharge or glow discharge for each target, the amount of ionization of the target metal can be periodically changed. The amount of ionization of the target metal can be periodically changed by periodically changing the current value at the time of arc discharging or glow discharging of the target at intervals of 0.01 to 0.5 minutes. Consequently, in the thickness direction of the coating layer, the content ratio of each metal element can be changed in each period.

When carrying out the above procedure, the composition of Al, Si and Cr is changed so that the amounts of Al and Si are decreased and the amount of Cr is increased, and then the composition of Al, Si and Cr is changed so that the amounts of Al and Si are increased and the amount of Cr is decreased, whereby the first coating layer 23 including the first layer and the second layer can be fabricated.

### Second Coating Layer 24

The second coating layer 24 may include Ti, Si, and N. That is, the second coating layer 24 may be a nitride layer (TiSiN layer) containing Ti and Si. Note that the expression “TiSiN layer” means that Ti, Si, and N are present at an arbitrary ratio, and does not necessarily mean that Ti, Si, and N are present at a ratio of 1:1:1.

As a result, for example, when a coefficient of friction of the second coating layer 24 is low, the welding resistance of the coated tool 1 can be improved. For example, when the hardness of the second coating layer 24 is high, the wear resistance of the coated tool 1 can be improved. For example, when an oxidation start temperature of the second coating layer 24 is high, the oxidation resistance of the coated tool 1 can be improved.

The second coating layer 24 may have a striped structure in cross-sectional observation by a transmission electron microscope. Specifically, the second coating layer 24 may include two or more layers located in the thickness direction. For example, the second coating layer 24 may include a third layer and a fourth layer alternately located in the thickness direction. The second coating layer 24 may include crystals having a cubic structure. In this case, each layer constituting the striped structure of the second coating layer 24 may contain crystals having a cubic structure.

Each layer included in the striped structure of the second coating layer 24 may contain Si and at least one metal element, and the content of the metal element may be different in each layer.

In the second coating layer 24, the content of Ti (hereinafter referred to as “Ti content”), the content of Si (hereinafter referred to as “Si content”), and the content of N (hereinafter referred to as “N content”) may each repeatedly increase and decrease along the thickness direction of the second coating layer 24. Note that the sum of Ti and Si of the metal elements contained in the second coating layer 24 may be 98 atomic % or more.

The coated tool 1 including the second coating layer 24 having such a configuration has high toughness of the coating layer, and is excellent in terms of impact resistance. Specifically, the coated tool 1 including the second coating layer 24 having such a configuration is excellent in terms of fracture resistance and chipping resistance.

The second coating layer 24 may have a portion in which the cycle of increase and decrease of the Ti content and the cycle of increase and decrease of the Si content are different. Here, the cycle of increase and decrease is, for example, a distance from a position at which the Ti content (Si content) is maximum (or minimum) to a position at which the Ti content (Si content) is next maximum (or minimum) along the thickness direction of the second coating layer 24.

The coated tool 1 including the second coating layer 24 having such a configuration has improved toughness and excellent impact resistance while maintaining high hardness.

The cycle of increase and decrease in the Ti content, the cycle of increase and decrease in the Si content, and the cycle of increase and decrease in the N content may be 1 nm or greater and 15 nm or less.

In the coated tool 1 including the second coating layer 24 having such a configuration, the residual stress inside the coating layer is relaxed, the adhesion of the coating layer is improved, and the impact resistance is improved.

The ratio of Ti in the metal elements of the second coating layer 24 may be 80 atomic % or more and 95 atomic % or less, and the ratio of Si in the metal elements of the second coating layer 24 may be 5 atomic % or more and 20 atomic % or less.

The coated tool 1 including the second coating layer 24 having such a configuration has improved adhesion of the coating layer, superior toughness of the coating layer and high impact resistance, while maintaining high hardness.

The ratio of Ti in the metal elements of the second coating layer 24 may be 82 atomic % or more and 90 atomic % or less.

The coated tool 1 including the second coating layer 24 having such a configuration has further improved toughness and high impact resistance.

As with the first coating layer 23, the second coating layer 24 may also be formed by the physical vapor deposition method. As an example, the second coating layer composed of TiSiN having a striped structure can be fabricated by using a titanium metal target and a titanium-silicon composite alloy target in an ion plating method and independently controlling voltage and current values at the time of arc discharge and glow discharge applied to these targets for each target.

In the coating layer 20 including the first coating layer 23 and the second coating layer 24, a lattice constant of a crystal having a cubic structure (hereinafter referred to as a “cubic crystal”) included in one of the two layers (the third layer and the fourth layer) of the striped structure of the second coating layer 24 is referred to as a first lattice constant. A lattice constant of the cubic crystal included in the other of the two layers (the third layer and the fourth layer) of the striped structure of the second coating layer 24 is referred to as a second lattice constant. Note that when the cubic crystal is located across two layers, a lattice constant of a portion of the cubic crystal located in one layer is referred to as the first lattice constant, and a lattice constant of a portion of the cubic crystal located in the other layer is referred to as the second lattice constant.

In this case, in the coated tool 1 according to the embodiment, a difference between the magnitude of the first lattice constant and the magnitude of the second lattice constant in the coating layer 20 may be greater than 0% and 0.10% or less.

Conventionally, in a coating layer in which two layers are alternately stacked, a difference between the magnitude of a lattice constant a1 of an a-axis of a crystal included in one layer and the magnitude of a lattice constant a2 of a crystal included in the other layer was large. For this reason, a large strain was present at an interface between the two layers, resulting in low thermal stability and low wear resistance and thermal shock resistance during cutting. On the other hand, in the coating layer 20 according to the embodiment, the difference between the magnitude of the lattice constant a1 of the a-axis of the cubic crystal included in one layer of the two layers (the third layer and the fourth layer) and the magnitude of the lattice constant a2 of the cubic crystal included in the other layer is small. For this reason, in the coating layer 20 according to the embodiment, the strain present at the interface between the two layers is small. Therefore, the coating layer 20 according to the embodiment has high thermal stability, and stability during cutting, i.e., wear resistance and thermal shock resistance are higher than those of conventional products.

In the coating layer 20, Si is contained in both the first coating layer 23 and the second coating layer 24. Thereby, the residual stress generated between the layers can be reduced, and thus the thermal stability can be further improved.

The coating layer 20 includes the first coating layer 23 containing Al and Cr. Consequently, the oxidation resistance and lubricity of the coating layer 20 can be improved.

The coating layer 20 includes the second coating layer 24 containing Ti. Consequently, chipping resistance can be improved.

Although an example in which the coating layer 20 includes both the first coating layer 23 and the second coating layer 24 has been described here, the coating layer 20 may include at least one of the first coating layer 23 and the second coating layer 24.

For example, the coating layer 20 may be configured to include only the first coating layer 23 among the first coating layer 23 and the second coating layer 24. In this case, the difference between the magnitude of the lattice constant a1 of the a-axis of the cubic crystal included in one layer of the two layers (the first layer 23a and the second layer 23b) of the first coating layer 23 and the magnitude of the lattice constant a2 of the cubic crystal included in the other layer may be greater than 0% and 0.1% or less.

Alternatively, the coating layer 20 may be configured to include only the second coating layer 24 among the first coating layer 23 and the second coating layer 24. In this case, the difference between the magnitude of the lattice constant a1 of the a-axis of the cubic crystal included in one layer of the two layers (the third layer and the fourth layer) of the second coating layer 24 and the magnitude of the lattice constant a2 of the cubic crystal included in the other layer may be greater than 0% and 0.10% or less. The third layer and the fourth layer may have the same crystal orientation or different crystal orientations.

### Intermediate Layer 22

An intermediate layer 22 may be located between the base body 10 and the coating layer 20. Specifically, the intermediate layer 22 has one surface (here, a lower surface) in contact with the upper surface of the base body 10 and another surface (here, an upper surface) in contact with the lower surface of the coating layer 20 (first coating layer 23).

The intermediate layer 22 has higher adhesion to the base body 10 than to the coating layer 20. Examples of a metal element having such characteristics include Zr, Hf, V, Nb, Ta, Cr, Mo, W, Al, Si, Y, and Ti. The intermediate layer 22 contains at least one metal element among the above-described metal elements. For example, the intermediate layer 22 may contain Ti. Note that Si is a metalloid element, but in the present specification, it is assumed that a metalloid element is also included in the metal element.

When the intermediate layer 22 contains Ti, the content of Ti in the intermediate layer 22 may be 1.5 atomic % or more. For example, the content of Ti in the intermediate layer 22 may be 2.0 atomic % or more.

The intermediate layer 22 may contain components other than the above-described metal elements (Zr, Hf, V, Nb, Ta, Cr, Mo, W, Al, Si, Y, and Ti). However, from the standpoint of adhesion to the base body 10, the intermediate layer 22 may contain at least 95 atomic % or more of the metal elements in a combined amount. More preferably, the intermediate layer 22 may contain 98 atomic % or more of the metal elements in a combined amount. Note that the ratio of the metal components in the intermediate layer 22 can be identified by, for example, analysis using an energy dispersive X-ray spectrometer (EDS) attached to a scanning transmission electron microscope (STEM).

As described above, in the coated tool 1 according to the embodiment, by providing the intermediate layer 22 having higher wettability with the base body 10 than the coating layer 20 between the base body 10 and the coating layer 20, the adhesion between the base body 10 and the coating layer 20 can be improved. Note that since the intermediate layer 22 also has high adhesion to the coating layer 20, the coating layer 20 is less likely to peel off from the intermediate layer 22.

Note that the thickness of the intermediate layer 22 may be, for example, 0.1 nm or greater and less than 20.0 nm.

### Cutting Tool

A configuration of a cutting tool including the coated tool 1 described above will be described with reference to FIG. 6. FIG. 6 is a front view illustrating an example of a cutting tool according to the embodiment.

As illustrated in FIG. 6, a cutting tool 100 according to the embodiment includes the coated tool 1 and a holder 70 for fixing the coated tool 1.

The holder 70 is a rod-like member extending from a first end (upper end in FIG. 6) toward a second end (lower end in FIG. 6). The holder 70 is made of, for example, steel or cast iron. In particular, it is preferable to use steel having high toughness among these members.

The holder 70 has a pocket 73 at an end portion on the first end side. The pocket 73 is a portion in which the coated tool 1 is mounted, and has a seating surface intersecting with the rotation direction of the work material and a binding side surface inclined with respect to the seating surface. A screw hole into which a screw 75 described later is screwed is provided on the seating surface.

The coated tool 1 is located in the pocket 73 of the holder 70, and is mounted on the holder 70 by the screw 75. That is, the screw 75 is inserted into the through hole 5 of the coated tool 1, and the tip end of the screw 75 is inserted into the screw hole formed in the seating surface of the pocket 73, and the screw portions are screwed together. Thus, the coated tool 1 is mounted on the holder 70 such that the cutting edge portion protrudes outward from the holder 70.

In the embodiment, a cutting tool used for so-called turning processing is exemplified. Examples of the turning processing include boring, external turning, and groove-forming. Note that, a cutting tool is not limited to those used in the turning processing. For example, the coated tool 1 may be used as a cutting tool used for milling processing. Examples of the cutting tool used for milling processing may include milling cutters such as a plain milling cutter, a face milling cutter, a side milling cutter, and a groove milling cutter, and end mills such as a single-blade end mill, a multi-blade end mill, a taper-blade end mill, and a ball end mill.

### Example

An example of the present disclosure will be specifically described below. The present disclosure is not limited to the following example.

Samples No. 1 to No. 6 each having the coating layer provided on the base body 10 made of WC-based cemented carbide containing WC particles as a hard phase component and Co as a main component of a binding phase were fabricated. Each of the coating layers of Samples No. 1 to No. 6 has a striped structure in cross-sectional observation by a transmission electron microscope. Among Samples No. 1 to No. 6, Samples No. 1 to No. 3 correspond to Examples of the present disclosure, and Samples No. 4, No. 5, and No. 6 correspond to Comparative Examples.

Sample No. 1 was a coated tool in which the base body was made of WC, the intermediate layer was made of a Ti-containing layer, the first coating layer was made of an AlCrSiN layer, and the second coating layer was made of a TiSiN layer. Sample No. 1 corresponds to the example of the present disclosure.

The base body was heated under a reduced pressure environment of 1×10⁻³ Pa to set a surface temperature to 550° C. Next, an argon gas was introduced as an atmospheric gas, and the pressure was maintained at 3.0 Pa. Next, a bias voltage was set to −400 V, and an argon bombardment treatment was performed for 11 minutes. Then, the pressure was reduced to 0.1 Pa, an arc current of 150 A was applied to the Ti metal evaporation source, and a treatment was performed for 0.3 minutes to form a Ti-containing layer as an intermediate layer on a surface of the base body. The argon bombardment treatment and the Ti-containing intermediate layer forming treatment were repeated three times in total to form an intermediate layer having a layer thickness of 8 nm. However, in the second and third argon bombardment treatments, the bias voltage was set to −200 V.

### Treatment Conditions of Argon Bombardment Treatment

(1) Bias voltage: −400 V
(2) Pressure: 3 Pa
(3) Treatment time: 11 minutes

### Film Forming Conditions of Ti-Containing Layer

(1) Arc current: 150 A
(2) Bias voltage: −400 V
(3) Pressure: 0.1a
(4) Treatment time: 0.3 minutes

### Conditions of Second and Subsequent Argon Bombardment Treatments

(1) Bias voltage: −200 V
(2) Pressure: 3 Pa
(3) Treatment time: 1 minute

The Ti-containing layer may contain other metal elements by diffusion, for example.

The Ti-containing layer may contain 50 to 98 atomic % of a metal element other than Ti.

Then, the first coating layer was formed. An atmospheric gas and a N₂ gas as an N source were introduced into a chamber in which the base body was accommodated, and the internal pressure of the chamber was maintained at 3 Pa. Next, a bias voltage of −130 V and arc currents of 135 to 150 A, 120 to 150 A, and 110 to 120 A were applied to the Al metal, Cr metal, and Al₅₂Si₄₈ alloy evaporation sources, respectively, for 15 minutes, with each arc current repeatedly applied at a cycle of 0.04 minutes, whereby an (Al₅₀Cr₄₃Si₇)N/(Al₄₈Cr₄₅Si₇)N layer as the first coating layer having an average thickness of 1.8 μm was formed.

Then, the second coating layer was formed. A bias voltage of −100 V and arc currents of 100 to 200 A and 100 to 200 A were applied to the Ti metal and Ti₅₂Si₄₈ alloy evaporation sources, respectively, for 10 minutes, with each arc current repeatedly applied at a cycle of 0.04 minutes, whereby a (Ti₉₁Si₉)N/(Ti₈₉Si₁₁)N layer as the second coating layer having an average thickness of 1.2 μm was formed.

Samples No. 2 to No. 6 were fabricated according to the fabrication method of Sample No. 1 by changing the metal or alloy evaporation source.

For each of Samples No. 1 to No. 6, the lattice constant of the cubic crystal contained in the coating layer was measured.

The lattice constant was measured by electron beam diffractometry using a transmission electron microscope JEM ARM200F or by fast Fourier transformation of TEM images.

The measurement conditions are as follows.

Acceleration voltage: 200 kV

Two-flute cemented carbide ball end mills (model number: 2KMBL0200-0800-54) of the coated tools of Samples No. 1 to No. 6 were used under the following conditions.

### Cutting Test Conditions

(1) Cutting method: pocket machining
(2) Work material: SKDIIH
(3) Rotational speed: 16900 min⁻¹
(4) Table feed: 1320 mm/min
(5) Cutting amount (ap×ae): 0.08 mm×0.2 mm
(6) Cutting state: Wet
(7) Coolant: Oil mist
(8) Evaluation method: Determination was made based on the number of impacts until chipping occurred.

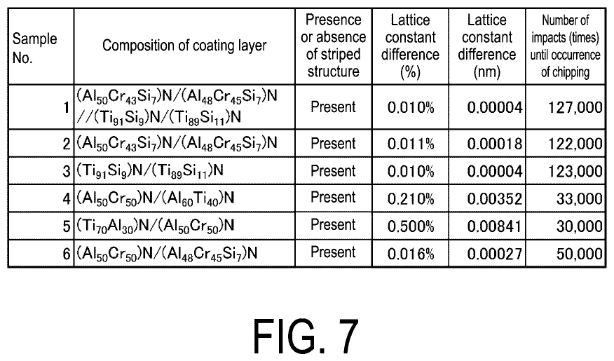

FIG. 7 is a table showing a configuration of the coating layer, a measurement result of the lattice constant, and a result of the cutting test in Samples No. 1 to No. 6. Here, a lattice constant difference (nm) shown in FIG. 7 is represented by |L1−L2| where the first lattice constant is denoted as L1 and the second lattice constant is denoted as L2. A lattice constant difference (%) is represented by |L1−L2|/{(L1+L2)/2}.

The coating layer of Sample No. 1 includes a first coating layer and a second coating layer. The first coating layer includes a first layer and a second layer alternately located in the thickness direction. The second coating layer includes a third layer and a fourth layer alternately located in the thickness direction. The first layer and the second layer may each contain Al, Cr, Si, and N. The ratios of Al, Cr and Si in the metal elements of the first layer are 50 atomic %, 43 atomic % and 7 atomic %, respectively, and the ratios of Al, Cr and Si in the metal elements of the second layer are 48 atomic %, 46 atomic % and 6 atomic %, respectively. In addition, the third layer and the fourth layer include Ti and Si. The ratios of Ti and Si in the metal elements of the third layer are 91 atomic % and 9 atomic %, respectively, and the ratios of Ti and Si in the metal elements of the fourth layer are 89 atomic % and 11 atomic %, respectively.

The coating layer of Sample No. 2 includes only the first coating layer among the first coating layer and the second coating layer. The first coating layer includes a first layer and a second layer alternately located in the thickness direction, and the first layer and the second layer each include Al, Cr, Si, and N. The ratios of Al, Cr and Si in the metal elements of the first layer are 50 atomic %, 43 atomic % and 7 atomic %, respectively, and the ratios of Al, Cr and Si in the metal elements of the second layer are 48 atomic %, 46 atomic % and 6 atomic %, respectively.

The coating layer of Sample No. 3 includes the second coating layer among the first coating layer and the second coating layer. The second coating layer includes a third layer and a fourth layer alternately located in the thickness direction, and the third layer and the fourth layer each include Ti, Si, and N. The ratios of Ti and Si in the metal elements of the third layer are 91 atomic % and 9 atomic %, respectively, and the ratios of Ti and Si in the metal elements of the fourth layer are 89 atomic % and 11 atomic %, respectively.

The coating layer of Sample No. 4 includes two layers (referred to as “fifth layer” and “sixth layer”, respectively) alternately located in the thickness direction. The fifth layer includes Al, Cr, and N, and the sixth layer includes Al, Ti, and N. The ratios of Al and Cr in the metal elements of the fifth layer are 50 atomic % and 50 atomic %, respectively, and the ratios of Al and Ti in the metal elements of the sixth layer are 60 atomic % and 40 atomic %, respectively.

The coating layer of Sample No. 5 includes two layers (referred to as “seventh layer” and “eighth layer”, respectively) alternately located in the thickness direction. The seventh layer includes Ti, Al, and N, and the eighth layer includes Al, Cr, and N. The ratios of Ti and Al in the metal elements of the seventh layer are 70 atomic % and 30 atomic %, respectively, and the ratios of Al and Cr in the metal elements of the eighth layer are 50 atomic % and 50 atomic %, respectively.

The coating layer of Sample No. 6 includes two layers (referred to as “seventh layer” and “eighth layer”, respectively) alternately located in the thickness direction. The seventh layer includes Al, Cr, and N, and the eighth layer includes Al, Cr, Si, and N. The ratios of Ti and Al in the metal elements of the seventh layer are 50 atomic % and 50 atomic %, respectively, and the ratios of Al, Cr and Si in the metal elements of the eighth layer are 48 atomic %, 46 atomic % and 6 atomic %, respectively.

As shown in FIG. 7, Sample No. 1 had a lattice constant difference (%) of 0.010% and a lattice constant difference (nm) of 0.00004 nm. Sample No. 2 had a lattice constant difference (%) of 0.016% and a lattice constant difference (nm) of 0.00027 nm. Sample No. 3 had a lattice constant difference (%) of 0.010% and a lattice constant difference (nm) of 0.00004 nm. Sample No. 4 had a lattice constant difference (%) of 0.210% and a lattice constant difference (nm) of 0.00352 nm. Sample No. 5 had a lattice constant difference (%) of 0.500% and a lattice constant difference (nm) of 0.00841 nm. Sample No. 6 had a lattice constant difference (%) of 0.022% and a lattice constant difference (nm) of 0.00036 nm. As described above, Samples No. 1 to No. 3 corresponding to Examples of the present disclosure have smaller lattice constant differences than those of Samples No. 4 and No. 5 corresponding to Comparative Examples. In addition, Sample No. 6 does not contain Si in at least one of the respective layers of the striped structure. From this result, it can be seen that the coated tool according to the present disclosure has high thermal stability. Note that although Sample No. 1 includes the first coating layer and the second coating layer, the result shown in FIG. 7 is the difference between the magnitude of the first lattice constant and the magnitude of the second lattice constant in the second coating layer.

As shown in FIG. 7, the number of impacts until occurrence of chipping in the cutting test was 127,000 times for Sample No. 1, 122,000 times for Sample No. 2, 123,000 times for Sample No. 3, 33,000 times for Sample No. 4, 30,000 times for Sample No. 5, and 50,000 times for Sample No. 6.

As described above, in Samples No. 1 to No. 3 corresponding to Examples of the present disclosure, the number of impacts until chipping occurred was larger, as compared with Samples No. 4, No. 5 and No. 6 as Comparative Examples. From this result, it can be seen that the coated tool according to the present disclosure has high wear resistance and thermal shock resistance during cutting.

As described above, a coated tool (as an example, the coated tool 1) includes a base body (as an example, the base body 10), and a coating layer (as an example, the coating layer 20) located on the base body. The coating layer includes crystals having a cubic structure. The coating layer has a striped structure in cross-sectional observation by a transmission electron microscope. The striped structure has two layers alternately located in a thickness direction. The two layers contain Si and at least one metal element. The two layers are different from each other in terms of the content of the metal element. The two layers each contain crystals having a cubic structure. When a lattice constant of a crystal having a cubic structure included in one layer of the two layers is referred to as a first lattice constant and a lattice constant of a crystal having a cubic structure included in the other layer of the two layers is referred to as a second lattice constant, the difference between a magnitude of the first lattice constant and a magnitude of the second lattice constant is greater than 0% and 0.1% or less.

Therefore, the coated tool according to the embodiment can enhance the thermal stability.

Note that the shape of the coated tool 1 illustrated in FIG. 1 is merely an example and does not limit the shape of the coated tool according to the present disclosure. The coated tool according to the present disclosure may include a body having, for example, a rotation axis and a rod-like shape extending from a first end toward a second end, a cutting edge located at the first end of the body, and a groove extending in a spiral shape from the cutting edge toward the second end of the body.

Further effects and variations can be readily derived by those skilled in the art. Thus, a wide variety of aspects of the present invention are not limited to the specific details and a representative embodiment represented and described above. Accordingly, various changes are possible without departing from the spirit or scope of the general inventive concepts defined by the appended claims and their equivalents.

### REFERENCE SIGNS

1 Coated tool
2 Tip body
5 Through hole
10 Base body
20 Coating layer
22 Intermediate layer
23 First coating layer
24 Second coating layer
70 Holder
73 Pocket
75 Screw
100 Cutting tool

1. A coated tool comprising:
a base body, and a coating layer located on the base body, wherein
the coating layer comprises crystals having a cubic structure,
the coating layer has a striped structure in cross-sectional observation by a transmission electron microscope,
the striped structure has two layers alternately located in a thickness direction,
the two layers
contain Si and at least one metal element,
are different from each other in terms of a content of the metal element, and
contain crystals having the cubic structure, respectively, and
when a lattice constant of a crystal having the cubic structure in one layer of the two layers is referred to as a first lattice constant and a lattice constant of a crystal having the cubic structure in the other layer of the two layers is referred to as a second lattice constant, a difference between a magnitude of the first lattice constant and a magnitude of the second lattice constant is greater than 0% and 0.1% or less.

2. The coated tool according to claim 1, wherein
the metal element is Al and Cr.

3. The coated tool according to claim 1, wherein
the metal element is Ti.

4. The coated tool according to claim 1, wherein
the coating layer comprises a first coating layer located on the base body and a second coating layer located on the first coating layer,
each of the first coating layer and the second coating layer has a striped structure in cross-sectional observation by a transmission electron microscope,
the striped structure of the first coating layer comprises a first layer and a second layer alternately located in a thickness direction,
the striped structure of the second coating layer comprises a third layer and a fourth layer alternately located in a thickness direction,
the first layer and the second layer each comprise Al, Cr, Si, and N, and
the third layer and the fourth layer each comprise Ti, Si, and N.

5. A cutting tool comprising:
a rod-like holder comprising a pocket at an end portion thereof; and
the coated tool according to claim 1 located in the pocket.
